(19) United States
(12) Patent Application Publication
(10) Pub. No.: US 2015/0130078 A1
(43) Pub. Date: May 14, 2015

(54) SEMICONDUCTOR CHIP AND SEMICONDUCTOR PACKAGE HAVING SAME

(71) Applicants: Ji-seok Hong, Yongin-si (KR); Won-keun Kim, Hwaseong-si (KR); Tae-je Cho, Hwaseong-si (KR); Jung-hwan Kim, Bucheon-si (KR)

(72) Inventors: Ji-seok Hong, Yongin-si (KR); Won-keun Kim, Hwaseong-si (KR); Tae-je Cho, Hwaseong-si (KR); Jung-hwan Kim, Bucheon-si (KR)

(21) Appl. No.: 14/499,591

(22) Filed: Sep. 29, 2014

(30) Foreign Application Priority Data
Nov. 12, 2013 (KR) 10-2013-0137119

(51) Int. Cl. H01L 25/18; H01L 23/00; H01L 23/34; H01L 23/48

(52) U.S. Cl. CPC H01L 25/18; H01L 23/481; H01L 24/17; H01L 23/34; H01L 2924/1431; H01L 2924/1434
USPC 257/774

(57) ABSTRACT

A semiconductor package of a POP structure includes first and second semiconductor packages, the second directly mounted on the first and containing a plurality of semiconductor chips. Chips in the second package are electrically connected via a through-electrode and the first and second packages are connected through a connection member disposed on the top surface of the first package.

### CROSS-REFERENCE TO RELATED APPLICATIONS

This application claims the benefit of Korean Patent Application No. 10-2013-0137119, filed on Nov. 12, 2013, in the Korean Intellectual Property Office, the disclosure of which is incorporated herein in its entirety by reference.

### BACKGROUND

Inventive concepts relate to a semiconductor apparatus, and more particularly, to a semiconductor package having a package-on-package (POP) structure.

Continued miniaturization of electronic products requires continued reduction in the size of electronic components and, in particular, on the reduction of semiconductor package size. Package-on-package structures may be employed to reduce the size of electronic components, however, increased package density may present difficulties with power dissipation and associated heat dissipation which can lead to reduced performance and/or reliability for the semiconductor component.

### SUMMARY

In exemplary embodiments in accordance with principles of inventive concepts, a semiconductor package of a package on package (POP) structure includes a substrate having a connection terminal on the upper surface thereof; a first semiconductor package including a first semiconductor chip mounted on the substrate and connected to the connection terminal, the first semiconductor package also including a molding member covering only a portion of the upper surface of the first semiconductor chip and the side surfaces thereof; a second semiconductor package including a plurality of second semiconductor chips which are stacked in a multi-layer structure, the second semiconductor chips having a second semiconductor chip through-electrode by which the second semiconductor chips are connected to each other; and a connection member disposed on a portion of the upper surface of the first semiconductor package left exposed by the molding member, wherein the second semiconductor package is mounted on the first semiconductor package and electrically connected to the first semiconductor package through the connection member.

In exemplary embodiments in accordance with principles of inventive concepts, the first semiconductor package includes a plurality of first semiconductor chips respectively having a plurality of first semiconductor chip through-electrodes, the first semiconductor chips electrically connected to each other through the plurality of first semiconductor chip through-electrodes.

In exemplary embodiments in accordance with principles of inventive concepts, the first semiconductor package comprises a plurality of connection pads on the upper surface thereof and a wire to electrically connect the plurality of connection pads and the substrate.

In exemplary embodiments in accordance with principles of inventive concepts, the first semiconductor chip is a different type of chip from the second semiconductor chips.

In exemplary embodiments in accordance with principles of inventive concepts, the first semiconductor chip comprises a logic semiconductor chip, and the plurality of second semiconductor chips comprise a memory semiconductor chip.

In exemplary embodiments in accordance with principles of inventive concepts, the plurality of second semiconductor chips are connected to each other via a micro pillar grid array (MPGA).

In exemplary embodiments in accordance with principles of inventive concepts, a planar area of the first semiconductor package is greater than that of the second semiconductor package.

In exemplary embodiments in accordance with principles of inventive concepts, the uppermost surface of the molding member is formed at substantially the same level as the uppermost surface of the first semiconductor chip.

In exemplary embodiments in accordance with principles of inventive concepts, a semiconductor package includes a heat-dissipation member which covers the upper surface of the molding member and the upper surface of the second semiconductor package.

In exemplary embodiments in accordance with principles of inventive concepts, the heat-dissipation member is of a constant thickness on the upper surface of the second semiconductor package and the upper surface of the first semiconductor package and further comprises a bonding member interposed between the heat-dissipation member and the upper surface of the second semiconductor package and between the heat-dissipation member and a portion of the upper surface of the first semiconductor package

In exemplary embodiments in accordance with principles of inventive concepts, a semiconductor package of a package on package (POP) structure includes a substrate having a connection terminal formed on the upper surface thereof; a first semiconductor package including a first semiconductor chip mounted on the substrate and connected to the connection terminal; a second semiconductor package including a plurality of second semiconductor chips; and a connection member interposed between the first semiconductor chip and the plurality of second semiconductor chips, wherein the second semiconductor package is mounted on the upper surface of the first semiconductor package, the first semiconductor chip is directly connected to the plurality of second semiconductor chips through the connection member, and an underfill member which partially covers the connection member is disposed between the upper surface of the first semiconductor package and the lower surface of the second semiconductor package.

In exemplary embodiments in accordance with principles of inventive concepts, the plurality of second semiconductor chips are stacked in a multi-layer structure and are connected to each other via a micro pillar grid array (MPGA).

In exemplary embodiments in accordance with principles of inventive concepts, a semiconductor package includes a molding member which covers a portion of the upper surface of the first semiconductor package and the side surfaces thereof, wherein the molding member is disposed so that at least a portion of the upper surface thereof contacts the underfill member.

In exemplary embodiments in accordance with principles of inventive concepts, a semiconductor package includes a molding member which covers the side surfaces of the first semiconductor package, wherein the uppermost surface of the molding member is formed at the same level as the uppermost surface of the first semiconductor package.

In exemplary embodiments in accordance with principles of inventive concepts, a molding member is spaced by a predetermined distance from the underfill member.

In exemplary embodiments in accordance with principles of inventive concepts, a semiconductor package, includes a substrate having a connection terminal on the upper surface thereof; a first semiconductor package including a first semiconductor chip mounted on the substrate and connected to the connection terminal, the first semiconductor package also including a molding member covering only a portion of the upper surface of the first semiconductor chip and the side surfaces thereof; a second semiconductor package including a plurality of second semiconductor chips which are stacked in a multi-layer structure, the second semiconductor chips having a second semiconductor chip through-electrode by which the second semiconductor chips are connected to each other; a connection member disposed on a portion of the upper surface of the first semiconductor package left exposed by the molding member, wherein the second semiconductor package is mounted on the first semiconductor package and electrically connected to the first semiconductor package through the connection member which extends through an underfill member in contact with the upper surface of a semiconductor chip in the first semiconductor package and with the lower surface of a lower-most semiconductor chip of the second semiconductor package; and a heat-dissipation member which covers the upper surface of the molding member and the upper surface of the second semiconductor package.

In exemplary embodiments in accordance with principles of inventive concepts, second semiconductor chips are all the same type of chip.

In exemplary embodiments in accordance with principles of inventive concepts, an electronic system includes a semiconductor package which includes a substrate having a connection terminal on the upper surface thereof; a first semiconductor package including a first semiconductor chip mounted on the substrate and connected to the connection terminal, the first semiconductor package also including a molding member covering only a portion of the upper surface of the first semiconductor chip and the side surfaces thereof; a second semiconductor package including a plurality of second semiconductor chips which are stacked in a multi-layer structure, the second semiconductor chips having a second semiconductor chip through-electrode by which the second semiconductor chips are connected to each other; a connection member disposed on a portion of the upper surface of the first semiconductor package left exposed by the molding member, wherein the second semiconductor package is mounted on the first semiconductor package and electrically connected to the first semiconductor package through the connection member which extends through an underfill member in contact with the upper surface of a semiconductor chip in the first semiconductor package and with the lower surface of a lower-most semiconductor chip of the second semiconductor package; and a heat-dissipation member which covers the upper surface of the molding member and the upper surface of the second semiconductor package, wherein the second semiconductor chips are memory chips.

In exemplary embodiments in accordance with principles of inventive concepts, a solid state drive (SSD) includes a semiconductor package which includes a substrate having a connection terminal on the upper surface thereof; a first semiconductor package including a first semiconductor chip mounted on the substrate and connected to the connection terminal, the first semiconductor package also including a molding member covering only a portion of the upper surface of the first semiconductor chip and the side surfaces thereof; a second semiconductor package including a plurality of second semiconductor chips which are stacked in a multi-layer structure, the second semiconductor chips having a second semiconductor chip through-electrode by which the second semiconductor chips are connected to each other; a connection member disposed on a portion of the upper surface of the first semiconductor package left exposed by the molding member, wherein the second semiconductor package is directly mounted on the first semiconductor package and electrically connected to the first semiconductor package through the connection member which extends through an underfill member in contact with the upper surface of a semiconductor chip in the first semiconductor package and with the lower surface of a lower-most semiconductor chip of the second semiconductor package; and a heat-dissipation member which covers the upper surface of the molding member and the upper surface of the second semiconductor package, wherein the second semiconductor chips are memory chips, wherein the first semiconductor chip is a memory controller.

In exemplary embodiments in accordance with principles of inventive concepts a mobile telephone includes a semiconductor package, that includes a substrate having a connection terminal on the upper surface thereof; a first semiconductor package including a first semiconductor chip mounted on the substrate and connected to the connection terminal, the first semiconductor package also including a molding member covering only a portion of the upper surface of the first semiconductor chip and the side surfaces thereof; a second semiconductor package including a plurality of second semiconductor chips which are stacked in a multi-layer structure, the second semiconductor chips having a second semiconductor chip through-electrode by which the second semiconductor chips are connected to each other; a connection member disposed on a portion of the upper surface of the first semiconductor package left exposed by the molding member, wherein the second semiconductor package is directly mounted on the first semiconductor package and electrically connected to the first semiconductor package through the connection member which extends through an underfill member in contact with the upper surface of a semiconductor chip in the first semiconductor package and with the lower surface of a lower-most semiconductor chip of the second semiconductor package; and a heat-dissipation member which covers the upper surface of the molding member and the upper surface of the second semiconductor package.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view of a semiconductor package of a package on package (POP) structure, in accordance with principles of inventive concepts;

FIGS. 2 to 5 are cross-sectional views of semiconductor packages of a POP structure, according to other embodiments of the inventive concept;

FIGS. 6 to 9 are cross-sectional views sequentially showing a portion of a method of manufacturing a semiconductor package of a POP structure, in accordance with principles of inventive concepts;

FIGS. 10 to 12 are cross-sectional views sequentially showing a portion of a method of manufacturing a semiconductor package of a POP structure, according to another exemplary embodiment in accordance with principles of inventive concepts;

FIG. 13 is a block diagram of a memory card including a semiconductor package in accordance with principles of inventive concepts;

FIG. 14 is a block diagram of an electronic system including a semiconductor package in accordance with principles of inventive concepts;

FIG. 15 is a top view of a solid state drive (SSD) device to which a semiconductor package in accordance with principles of inventive concepts is applied; and

FIG. 16 is a perspective view of an electronic device to which a semiconductor package in accordance with principles of inventive concepts is applied.

### DETAILED DESCRIPTION OF THE EMBODIMENTS

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example. may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

.

Expressions such as “at least one of,” when preceding a list of elements, modify the entire list of elements and do not modify the individual elements of the list.

Hereinafter, exemplary embodiments in accordance with principles of inventive concepts will be explained in detail with reference to the accompanying drawings.

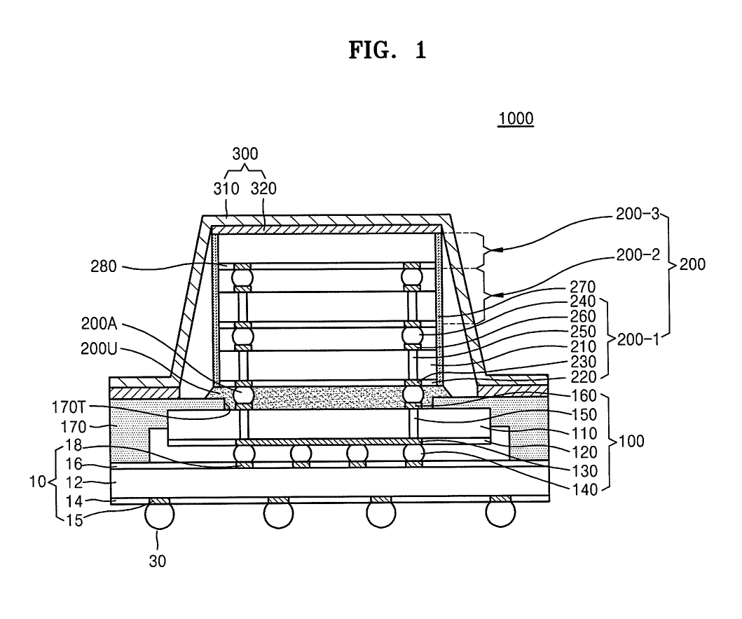

FIG. 1 is a cross-sectional view of an exemplary embodiment of a semiconductor package 1000 having a package on package (POP) structure in accordance with principles of inventive concepts. Semiconductor package 1000 may include a substrate 10, a first semiconductor package 100, a second semiconductor package 200, a package connection member 200A, and an underfill member 200U. The first semiconductor package 100 may include a first semiconductor chip 110 located on the substrate 10 and having a first through-electrode 150 and a molding member 170 which covers a portion of the upper surface of the first semiconductor chip 110 and side surfaces thereof. The second semiconductor package 200 may include a plurality of second semiconductor chip packages 200-1, 200-2, and 200-3 located on the first semiconductor package 100. The package connection member 200A and the underfill member 200U may respectively electrically and mechanically connect the first semiconductor package 100 and the second semiconductor package 200. The semiconductor package 1000 of a POP structure may additionally include a heat-dissipation member 300 which covers a portion of the upper surface of the molding member 170 and the upper surface of the second semiconductor chip package 200-3 (the topmost of semiconductor chip packages 200 in this exemplary embodiment).

In exemplary embodiments in accordance with principles of inventive concepts substrate 10 is a support substrate upon which the first semiconductor package 100 is mounted and may include a body layer 12, a lower protective layer 14, a lower pad 15, an upper protective layer 16, an upper pad 18, and an external connection member 30. The substrate 10 may be formed on the basis of at least one selected from among: a ceramic substrate, a printed circuit board (PCB), an organic substrate, and an interposer substrate. In exemplary embodiments in accordance with principles of inventive concepts substrate 10 may be formed with an active wafer, for example.

A single- or multi-layer wiring pattern may be formed inside the body layer 12, and the lower pad 15 and the upper pad 18 may be electrically and/or physically connected through the wiring pattern. The lower protective layer 14 and the upper protective layer 16 function to protect the body layer 12 and may be formed of, for example, a solder resist.

The lower pad 15 may be formed on the lower surface of the body layer 12 and electrically and/or physically connected to the wiring pattern inside the body layer 12 by passing through the lower protective layer 14, for example. The lower pad 15 may be formed of a conductive material and on the lower surface of the body layer 12. An under bump metal (UBM) may be formed on the lower pad 15. The lower pad 15 may be formed of aluminum (Al) or copper (Cu) by a pulse plating method or a direct current (DC) plating method, for example. However, exemplary embodiments of lower pad 15 in accordance with principles of inventive concepts are not limited to these exemplary materials or methods.

The upper pad 18 may be formed on the upper surface of the body layer 12 and may be electrically and/or physically connected to the wiring pattern inside the body layer 12 by passing through the upper protective layer 16. In exemplary embodiments in accordance with principles of inventive concepts, for the upper pad 18, a material and a forming method are as described above with respect to the lower pad 15.

The external connection member 30 may be formed on the lower pad 15 and may function to mount the whole semiconductor package 1000 on an external system substrate or a main board, for example. The external connection member 30 may be formed of at least one selected from among conductive materials, for example, Cu, Al, silver (Ag), tin (Sn), gold (Au), or solder. The external connection member 30 may be formed in multiple layers or a single layer. The size of the external connection member 30 may be greater than that of a connection member 140 of the first semiconductor package 100 or a connection member 240 of the second semiconductor package 200.

The first semiconductor package 100 may include the first semiconductor chip 110, a passivation layer 120, a lower wiring pattern 130, the connection member 140, the first through-electrode 150, and an upper pad 160. The first semiconductor package 100 may be formed on the basis of an active wafer or an interposer substrate, for example. The term “active wafer” may refer to a wafer on which a semiconductor chip may be formed, such as a silicon wafer, for example. The first semiconductor chip 110 may include a IV group material wafer, such as a silicon wafer, or a III-V group compound wafer. The first semiconductor chip 110 may be formed with a monocrystalline wafer, such as a monocrystalline silicon wafer, for example. However, exemplary embodiments of the first semiconductor chip 110 are not limited to the monocrystalline wafer, and, in accordance with principles of inventive concepts, various wafers, such as an epitaxial wafer, a polished wafer, an annealed wafer, a silicon on insulator (SOI) wafer, and the like, may be used for the first semiconductor chip 110. By “epitaxial wafer” we mean a wafer obtained by growing a crystalline material on a monocrystalline silicon wafer.

In exemplary embodiments in accordance with principles of inventive concepts, the first semiconductor chip 110 may be a logic semiconductor chip. The first semiconductor chip 110 may be a microprocessor, for example, a central processing unit (CPU), a controller, an application specific integrated circuit (ASIC), or the like. In exemplary embodiments in accordance with principles of inventive concepts, the first semiconductor chip 110 may be an application processor (AP) used for a mobile phone or a smart phone, for example.

The first semiconductor chip 110 includes the first through-electrode 150 which passes through the inside thereof. In exemplary embodiments in accordance with principles of inventive concepts, the first through-electrode 150 may be a through silicon via (TSV). The TSV may include at least one conductive material selected from among, for example, Al, Au, beryllium (Be), bismuth (Bi), cobalt (Co), Cu, hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr). The first semiconductor chip 110 may be electrically and/or physically connected to the substrate 10 by electrically and/or physically connecting the first through-electrode 150 to the lower wiring pattern 130 and connecting the lower wiring pattern 130 to the upper pad 18 of the substrate 10 through the connection member 140. The lower wiring pattern 130 is formed on the passivation layer 120 so as to be connected to a plurality of connection members 140, and a material and a forming method of the lower wiring pattern 130 may be the same as described above with respect to the lower pad 15, and as a result, a detailed description thereof will not be repeated here.

In exemplary embodiments in accordance with principles of inventive concepts molding member 170 is formed so as to seal the first semiconductor package 100, and accordingly, the first semiconductor package 100 may be protected from the external environment. The molding member 170 may seal the side surfaces of the first semiconductor chip 110 and a portion of the upper surface thereof. The molding member 170 may include an insulating material. For example, the molding member 170 may be formed of an epoxy-group material, a thermosetting material, a thermoplastic material, an ultraviolet (UV) treated material, or the like. When the molding member 170 is formed of a thermosetting material, the molding member 170 may include a phenol-, acid anhydride- or amine-type hardener and an additive of an acrylic polymer. In exemplary embodiments in accordance with principles of inventive concepts, the molding member 170 may be formed of an epoxy molding compound (EMC). The molding member 170 may be formed by a molded underfill (MUF) method.

The molding member 170 may include an opening part 170T. The package connection member 200A and the underfill member 200U may be formed in the opening part 170T. In exemplary embodiments in accordance with principles of inventive concepts an upper surface region of the upper surface of the first semiconductor package 100, in which the package connection member 200A for connecting the upper pad 160 and the second semiconductor package 200 is formed, may be formed in a surface-exposed form without being covered and sealed by the molding member 170. The opening part 170T may extend in a lower direction with a constant width or a gradually narrowed width, for example.

The underfill member 200U may be formed so as to fill the upper surface of the first semiconductor chip 110, the package connection member 200A, and the lower surface of the second semiconductor chip package 200-1 located at the lowest part of the second semiconductor package 200.

In exemplary embodiments in accordance with principles of inventive concepts second semiconductor package 200 may include the plurality of second semiconductor chip packages 200-1, 200-2, and 200-3. The plurality of second semiconductor chip packages 200-1, 200-2, and 200-3 may be formed with semiconductor chip packages of a same type or semiconductor chip packages of different types. In exemplary embodiments in accordance with principles of inventive concepts, the plurality of second semiconductor chip packages 200-1, 200-2, and 200-3 are formed in a structure where semiconductor chip packages of a same type are stacked, and because a shape, a function, a connection method, and the like of each component are the same, the second semiconductor chip package 200-1 formed at the lowest part of the second semiconductor package 200 will be mainly described. Although the plurality of second semiconductor chip packages 200-1, 200-2, and 200-3 are shown as three packages, inventive concepts are not limited thereto, and one or more semiconductor chip packages may be stacked and formed, or fewer semiconductor chip packages may be stacked and form.

The second semiconductor chip package 200-1 may include a second semiconductor chip 210, a passivation layer 220, a lower pad 230, a connection member 240, a second through-electrode 250, and an upper pad 260.

The second semiconductor chip 210 may be formed on the basis of an active wafer or an interposer substrate, for example. In exemplary embodiments in accordance with principles of inventive concepts the material, shape, forming method, and the like of the second semiconductor chip 210 may be the same as described above with respect to the first semiconductor chip 110, and, as a result, a detailed description thereof will not be repeated here. The second semiconductor chip 210 may be a memory semiconductor device. The second semiconductor chip 210 may include at least one selected from among, for example, dynamic random access memory (DRAM), static RAM (SRAM), flash memory, electrically erasable programmable read-only memory (EEPROM), programmable RAM (PRAM), resistive RAM (RRAM), and magnetoresistive RAM (MRAM).

The second semiconductor chip 210 may have a size that is different from that of the first semiconductor chip 110. In exemplary embodiments in accordance with principles of inventive concepts, the second semiconductor chip 210 may be formed to have a planar area that is less than that of the first semiconductor chip 110. In exemplary embodiments in accordance with principles of inventive concepts, second semiconductor chip 210 and the first semiconductor chip 110 may be semiconductor chips of different types, which have different functions. As described above, in exemplary embodiments in accordance with principles of inventive concepts, the first semiconductor chip 110 may be a logic semiconductor chip, and the second semiconductor chip 210 may be a memory semiconductor chip. However, inventive concepts are not limited thereto.

In exemplary embodiments in accordance with principles of inventive concepts passivation layer 220 is formed on the lower surface of the second semiconductor chip 210 and functions to protect the second semiconductor chip 210 from the external environment. The passivation layer 220 may be formed with an oxide layer, a nitride layer, or a dual layer of an oxide layer and a nitride layer. The passivation layer 220 may be formed with an oxide layer or a nitride layer, for example, a silicon oxide (SiO₂) layer or a silicon nitride (SiNₓ) layer, by using a high density plasma chemical vapor deposition (HDP-CVD) process, for example.

The lower pad 230 may be formed of a conductive material and on the lower surface of the second semiconductor chip 210 and may be electrically and/or physically connected to the second through-electrode 250 by passing through the passivation layer 220. A UBM may be formed on the lower pad 230. The lower pad 230 may be formed of Al or Cu by a pulse plating method or a DC plating method, for example, but the lower pad 230 is not limited to those materials or methods.

The connection member 240 may be formed on the lower pad 230. The connection member 240 may be formed of a conductive material, for example, Cu, Al, Ag, Sn, Au, solder, for example, but the material of the connection member 240 is not limited thereto. The connection member 240 may be formed in multiple layers or a single layer. For example, when the connection member 240 is formed in multiple layers, the connection member 240 may include a Cu pillar and solder, and when the connection member 240 is formed in a single layer, the connection member 240 may include Sn—Ag solder or Cu, for example.

In exemplary embodiments in accordance with principles of inventive concepts, second through-electrode 250 may be connected to the lower pad 230 by passing through the second semiconductor chip 210 and second through-electrode 250 may be formed with at least one grid array selected from among a TSV, a pin grid array, a ball grid array, and an MPGA.

The second through-electrode 250 may include a barrier metal layer and a wiring metal layer. The barrier metal layer may include a stacked structure including one or more selected from among: Ti, Ta, titanium nitride (TiN), and tantalum nitride (TaN), for example. The wiring metal layer may include one or more of Al, Au, Be, Bi, Co, Cu, Hf, In, Mn, Mo, Ni, Pb, Pd, Pt, Rh, Re, Ru, Ta, Te, Ti, W, Zn, and Zr. For example, the wiring metal layer may include a stacked structure including one or more selected from among W, Al, and Cu, but the material of the second through-electrode 250 is not limited thereto.

In exemplary embodiments in accordance with principles of inventive concepts second semiconductor chip 210 may be electrically and/or physically connected through the second through-electrode 250 to second semiconductor chips of the other second semiconductor chip packages 200-2 and 200-3 stacked on the upper surface of the second semiconductor chip package 200-1. The second through-electrode 250 may be electrically and/or physically connected through the upper pad 260 and the connection member 240 to a lower pad of the second semiconductor chip package 200-2 stacked on the upper surface of the second semiconductor chip package 200-1. The connection member 240 may be, for example, a solder member, but inventive concepts are not limited thereto.

In exemplary embodiments in accordance with principles of inventive concepts, air gap 280 may be formed between every two of the plurality of second semiconductor chip packages 200-1, 200-2, and 200-3 forming the second semiconductor package 200. The air gap 280 may accommodate thermal expansion which may occur according to the stack of the plurality of second semiconductor chip packages 200-1, 200-2, and 200-3. In exemplary embodiments in accordance with principles of inventive concepts, the height of the air gap 280 in a direction that is vertical to the substrate 10 is equal to the sum of a height of the connection member 240 and a height of the upper pad 260.

The package connection member 200A may be electrically and/or physically connected to the second through-electrode 250 through the lower pad 230, and accordingly, the second semiconductor chip package 200-1 and the first semiconductor package 100 may be electrically and/or physically connected to each other. The package connection member 200A may be plural in number. The package connection member 200A may have, for example, a spherical shape, and the spherical shape may be modified so that upper and lower contact surfaces are somewhat flat. However, inventive concepts are not limited thereto, and the package connection member 200A may have a shape other than the spherical shape. In exemplary embodiments in accordance with principles of inventive concepts, the package connection member 200A may be formed with a solder ball. However, the package connection member 200A is not limited thereto and may have a flip chip connection structure having a grid array, such as a pin grid array, a ball grid array, or a land grid array, for example.

The second semiconductor package 200 may be sealed by a side surface molding member 270, and accordingly, the second semiconductor package 200 may be protected from the external environment, and a laminated structure of the plurality of second semiconductor chip packages 200-1, 200-2, and 200-3 may be rigidly maintained. The side surface molding member 270 may be formed by an MUF method, for example. The side surface molding member 270 may include an insulating material. The side surface molding member 270 is optional and may be omitted. When the side surface molding member 270 is omitted, the side surfaces of the second semiconductor chip 210 may be exposed to the external environment.

The heat-dissipation member 300 may be formed on the upper surface of the second semiconductor chip package 200-3, which is formed on the uppermost part of the second semiconductor package 200, and a portion of the upper surface of the molding member 170. In exemplary embodiments in accordance with principles of inventive concepts heat-dissipation member 300 is formed with a predetermined thickness in vertical a direction that is normal to the upper surface of the substrate 10 so as to cover the upper surface of the second semiconductor chip package 200-3 and a portion of the upper surface of the molding member 170 and extends along the second semiconductor chip package 200-3 and the molding member 170. In exemplary embodiments in accordance with principles of inventive concepts, when the heat-dissipation member 300 extends along the second semiconductor chip package 200-3 and the molding member 170, the heat-dissipation member 300 is spaced by a predetermined distance from the side surfaces of the second semiconductor package 200 without contacting the side surfaces of the second semiconductor package 200 and extends diagonally by forming a predetermined angle.

The heat-dissipation member 300 may include a heat-dissipation plate 310 and an adhesive member 320. The heat-dissipation plate 310 may be formed of at least one metallic material selected from among, for example, Ag, Al, Cu, Au, Zn, Ni, and iron (Fe) or an alloy thereof, for example. In exemplary embodiments in accordance with principles of inventive concepts, the heat-dissipation plate 310 may be formed of an Al alloy. The heat-dissipation plate 310 may be a thermal via or a heat slug. The heat-dissipation plate 310 may have a planar plate shape as illustrated in FIG. 1, but, a heat-dissipation plate 310 in accordance with principles of inventive concepts is not limited to a plate shape and may be formed in a shape of which the surface area is enlarged by patterning so that the surface thereof has an uneven pattern.

The adhesive member 320 may be interposed between the heat-dissipation plate 310 and the upper surface of the second semiconductor chip package 200-3 and between the heat-dissipation plate 310 and the upper surface of the molding member 170. The adhesive member 320 may be formed of at least one adhesive material selected from among: a molding layer, an adhesive layer, and a thermal interface material (TIM), for example. The adhesive member 320 may prevent weakening of adhesive strength due to a coefficient of thermal expansion (CTE) mismatch between different types of semiconductor packages when the first and second semiconductor packages 100 and 200 are stacked. In addition, warpage of the semiconductor package 1000 may be minimized due to a strong adhesive strength between the second semiconductor chip package 200-3 and the heat-dissipation plate 310 and the strength of the heat-dissipation plate 310.

The semiconductor package 1000 in accordance with principles of inventive concepts may be a POP in which a plurality of semiconductor packages are stacked and become one body or a system in chip (SIC) in which a logic semiconductor chip and one or more memory semiconductor chips are integrated in a single package. In exemplary embodiments in accordance with principles of inventive concepts, semiconductor package 1000 may realize a small form factor and a low profile because a second substrate formed with a PCB and the like may be omitted from the second semiconductor package 200 by connecting a plurality of semiconductor packages, including, for example, some of the same type of semiconductor chips, for example, the plurality of second semiconductor chip packages 200-1, 200-2, and 200-3, to each other through the second through-electrode 250 and directly electrically and/or physically connecting the second semiconductor package 200 to the first semiconductor package 100 through the package connection member 200A. By omitting a separate molding member, such as an epoxy resin, from the second semiconductor package 200 and directly forming the heat-dissipation member 300, heat dissipation characteristics of the entire package 1000 may be improved because heat generated by the first semiconductor package 100 is not trapped in the second semiconductor package 200.

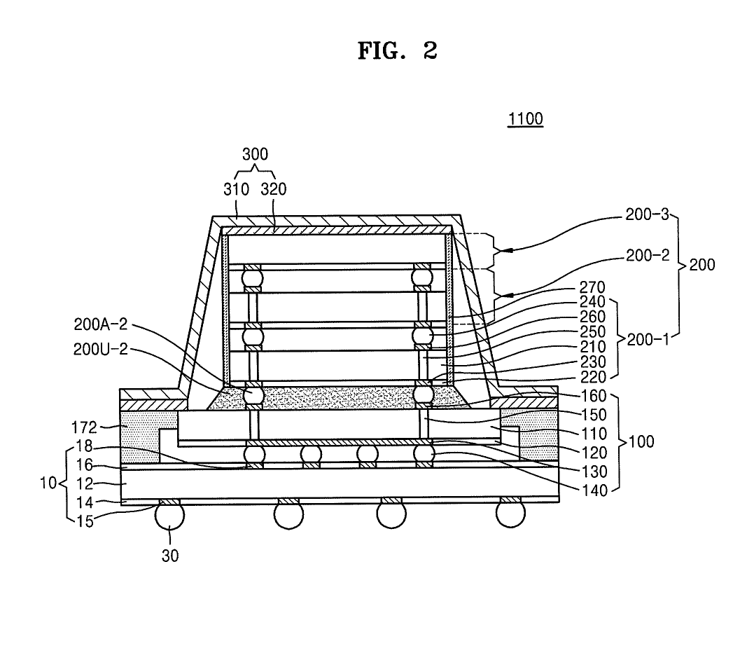

FIG. 2 is a cross-sectional view of a semiconductor package 1100 according to another exemplary embodiment in accordance with principles of inventive concepts. Semiconductor package 1100 may include the substrate 10, the first semiconductor package 100, the second semiconductor package 200, a package connection member 200A-2, and an underfill member 200U-2. The semiconductor package 1100 illustrated in FIG. 2 may have the same configuration as the semiconductor package 1000 illustrated in FIG. 1 except for the package connection member 200A-2 and the underfill member 200U-2. Because like reference numerals denote like elements, reference numerals in FIG. 2 refer to reference numerals of components shown in FIG. 1.

A molding member 172 of the semiconductor package 1100 is formed to cover the side surfaces of the first semiconductor chip 110 and to leave uncovered the upper surface of the first semiconductor chip 110. That is, the molding member 172 is not formed on the upper surface of the first semiconductor chip 110. As a result, the level of the uppermost surface of the molding member 172 may be formed to be substantially the same as the level of the uppermost surface of the first semiconductor chip 110. In addition, unlike the molding member 170 illustrated in FIG. 1, in this exemplary embodiment in accordance with principles of inventive concepts, the molding member 172 does not include the separate opening part 170T illustrated in FIG. 1. A material and a forming method of the molding member 172 may be the same as those of the molding member 170 described with reference to FIG. 1, and as a result, a detailed description thereof is not repeated here.

In exemplary embodiments in accordance with principles of inventive concepts, package connection member 200A-2 may be formed on the upper surface of the first semiconductor chip 110 to be connected to the upper pad 160 of the first semiconductor chip 110 and connected to the lower pad 230 of the second semiconductor chip package 200-1 laminated on the lowest part of the second semiconductor package 200. Therefore, the package connection member 200A-2 may be a medium for an electrical and/or physical connection between the first semiconductor chip 110 and the second semiconductor package 200.

In exemplary embodiments in accordance with principles of inventive concepts, underfill member 200U-2 is formed to surround both side parts of the package connection member 200A-2 and to fill in a space between the upper surface of the first semiconductor chip 110 of the first semiconductor package 100 and the lower surface of the second semiconductor chip package 200-1. Unlike the underfill member 200U illustrated in FIG. 1, the underfill member 200U-2 is formed not to contact the molding member 172. A material and a forming method of the underfill member 200U-2 may be the same as those of the underfill member 200U described with reference to FIG. 1, and thus, a detailed description thereof is not repeated here.

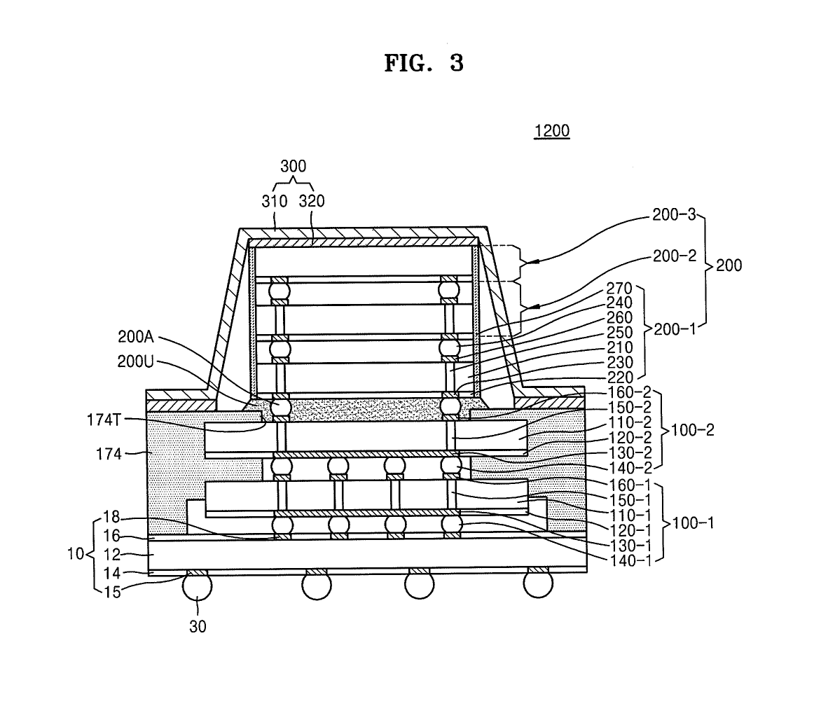

FIG. 3 is a cross-sectional view of a semiconductor package 1200 according to another exemplary embodiment in accordance with principles of inventive concepts. Semiconductor package 1200 may include the substrate 10, a plurality of first semiconductor chip packages 100-1 and 100-2, the second semiconductor package 200, the package connection member 200A, and the underfill member 200U. The semiconductor package 1200 illustrated in FIG. 3 may have the same configuration as the semiconductor package 1000 illustrated in FIG. 1 except for the first semiconductor package 100 which includes the plurality of first semiconductor chip packages 100-1 and 100-2. Because like reference numerals denote like elements, reference numerals in FIG. 3 refer to reference numerals of components shown in FIG. 1.

The semiconductor package 1200 in accordance with principles of inventive concepts is formed to have a structure in which the plurality of first semiconductor chip packages 100-1 and 100-2 are stacked. The plurality of first semiconductor chip packages 100-1 and 100-2 may include first semiconductor chips 110-1 and 110-2, passivation layers 120-1 and 120-2, lower wiring patterns 130-1 and 130-2, connection members 140-1 and 140-2, through-electrodes 150-1 and 150-2, and upper pads 160-1 and 160-2, respectively. The first semiconductor chips 110-1 and 110-2 may be different from each other, but the passivation layers 120-1 and 120-2, the lower wiring patterns 130-1 and 130-2, the connection members 140-1 and 140-2, the through-electrodes 150-1 and 150-2, and the upper pads 160-1 and 160-2 have the same materials, the same shapes, and the same forming methods thereof as those described with reference to FIG. 1, respectively, and thus, a detailed description thereof is not repeated here.

The first semiconductor chips 110-1 and 110-2 may be formed on the basis of an active wafer or an interposer substrate. Materials and forming methods of the first semiconductor chips 110-1 and 110-2 are the same as those described with reference to FIG. 1, and thus, a detailed description thereof is not repeated here. The first semiconductor chips 110-1 and 110-2 may be the same type of semiconductor chips, for example, logic semiconductor devices. In exemplary embodiments in accordance with principles of inventive concepts, the first semiconductor chip 110-1 mounted in a lower first semiconductor chip package 100-1 may include a CPU or an application processor AP used for a mobile phone or a smart phone, and the first semiconductor chip 110-2 mounted in an upper first semiconductor chip package 100-2 stacked on the upper surface of the lower first semiconductor chip package 100-1 may be a graphic chip or an application specific integrated circuit (ASIC), for example.

The plurality of first semiconductor chip packages 100-1 and 100-2 may be formed to be vertically stacked in a flip-chip form. The first semiconductor chip package 100-1 formed on the lower part of the plurality of first semiconductor chip packages 100-1 and 100-2 may be connected to the connection member 140-1 through the lower pad 130-1 to be thereby electrically and/or physically connected to the substrate 10 and may be connected to the upper pad 160-1 through the first through-electrode 150-1 and connected through the connection member 140-2 to the upper first semiconductor chip package 100-2 stacked on the lower first semiconductor chip package 100-1 to be thereby electrically and/or physically connected to the upper first semiconductor chip package 100-2. In exemplary embodiments in accordance with principles of inventive concepts, the materials and forming methods of the through-electrodes 150-1 and 150-2 are the same as those of the first through-electrode 150 described with reference to FIG. 1, and thus, a detailed description thereof is not repeated here.

A molding member 174 may be formed to cover a portion of the upper surface of the upper first semiconductor chip package 100-2 and to cover the side surfaces of the upper and lower first semiconductor chip packages 100-1 and 100-2. The molding member 174 may be formed to seal the plurality of first semiconductor chip packages 100-1 and 100-2, and accordingly, the plurality of first semiconductor chip packages 100-1 and 100-2 may be protected from the external environment. Like the molding member 170 illustrated in FIG. 1, the molding member 174 may include an opening part 174T on the upper part thereof. The package connection member 200A and the underfill member 200U may be formed in the opening part 174T. An upper surface region of the upper surface of the first semiconductor package 100-1, in which the package connection member 200A for connecting the upper pad 160-1 and the second semiconductor package 200 is formed, may be formed in a surface-exposed form without being covered and sealed by the molding member 174. The opening part 174T may extend in a lower direction with a constant width or a gradually narrowed width. In exemplary embodiments in accordance with principles of inventive concepts, the material and forming method of the molding member 174 are the same as those of the molding member 170 described with reference to FIG. 1, and thus, a detailed description thereof is not repeated here.

The underfill member 200U may be formed to fill the upper surface of the upper first semiconductor chip 110-1, the package connection member 200A, and the lower surface of the second semiconductor chip package 200-1 located at the lowest part of the second semiconductor package 200.

Unlike the semiconductor package 1000 illustrated in FIG. 1, the semiconductor package 1200 in accordance with principles of inventive concepts differs in that the first semiconductor package 100 includes the plurality of first semiconductor chip packages 100-1 and 100-2, and the first semiconductor chip 110-1 mounted in the lower first semiconductor chip package 100-1 and the first semiconductor chip 110-2 mounted in the upper first semiconductor chip package 100-2 are formed with a logic semiconductor device and a CPU or graphic chip, respectively, to thereby form a logic semiconductor device package.

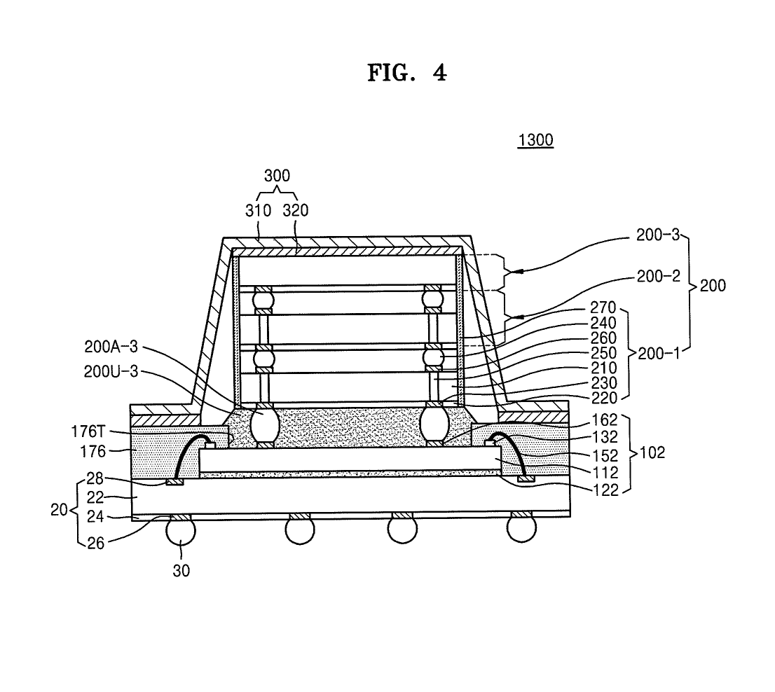

FIG. 4 is a cross-sectional view of a semiconductor package 1300 according to another exemplary embodiment in accordance with principles of inventive concepts. Semiconductor package 1300 may include a substrate 20, a first semiconductor package 102, the second semiconductor package 200, a package connection member 200A-3, and an underfill member 200U-3. Unlike the semiconductor package 1000 illustrated in FIG. 1, the semiconductor package 1300 illustrated in FIG. 4 includes the first semiconductor package 102 without the first through-electrode 150, and instead, a bonding wire 152 may electrically and/or physically connect the first semiconductor package 102 to the substrate 20. The substrate 20 is also different from the substrate 10 illustrated in FIG. 1 with respect to components and a connection form. However, because the configuration of the second semiconductor package 200, the heat-dissipation member 300, and the like are the same, for the semiconductor package 1000 and the semiconductor package 1300, like reference numerals in FIG. 1 denote like components shown in FIG. 1.

The semiconductor package 1300 in accordance with principles of inventive concepts is formed so that the first semiconductor package 102 has a structure connected to the substrate 20 through the bonding wire 152 instead of the first through-electrode 150. The substrate 20 is a support substrate upon which the first semiconductor package 102 may be mounted and may include a body layer 22, a lower protective layer 24, a lower pad 26, an upper pad 28, and the external connection member 30. The substrate 20 may be formed on the basis of at least one selected from among: a ceramic substrate, a PCB, an organic substrate, and an interposer substrate, for example. In exemplary embodiments in accordance with principles of inventive concepts, the substrate 20 may be formed with an active wafer. A single- or multi-layer wiring pattern may be formed inside the body layer 22, and the lower pad 26 and the upper pad 28 may be electrically and/or physically connected through the wiring pattern. The lower protective layer 24 functions to protect the body layer 22 and may be formed of, for example, a solder resist.

The lower pad 26 may be formed on the lower surface of the body layer 22 and may be electrically and/or physically connected to the wiring pattern inside the body layer 22 by passing through the lower protective layer 24. The upper pad 28 may be formed on the upper surface of the body layer 22 and may be electrically and/or physically connected to a first semiconductor chip 112 through the bonding wire 152 of the first semiconductor package 102, for example. In exemplary embodiments in accordance with principles of inventive concepts materials of the forming methods of the lower pad 26 and the upper pad 28 are the same as those of the lower pad 15 and the upper pad 18 described with reference to FIG. 1, and thus, a detailed description thereof is not repeated here.

The first semiconductor package 102 may include the first semiconductor chip 112, a passivation layer 12, an upper pad 132, the bonding wire 152, and a package connection pad 162. The first semiconductor package 102 may be formed on the basis of an active wafer or an interposer substrate. In exemplary embodiments in accordance with principles of inventive concepts a material and a forming method of the first semiconductor chip 112 are the same as those of the first semiconductor chip 110 described with reference to FIG. 1, and thus, a detailed description thereof is not repeated here.

In exemplary embodiments in accordance with principles of inventive concepts, the first semiconductor chip 112 may be a logic semiconductor chip. The first semiconductor chip 112 may be a microprocessor, for example, a CPU, a controller, an ASIC, or the like. The first semiconductor chip 112 has the upper pad 132 formed on a portion of the upper surface thereof and has the bonding wire 152 for connecting the upper pad 132 and the upper pad 28 of the substrate 20. The first semiconductor chip 112 may be electrically and/or physically connected to the substrate 20 through the upper pad 132 and the bonding wire 152. Although the upper pad 132 is shown less than the upper pad 160 of the first semiconductor package 100 illustrated in FIG. 1, in exemplary embodiments in accordance with principles of inventive concepts a material and a forming method of the upper pad 132 are the same as those of the upper pad 160 illustrated in FIG. 1, a detailed description thereof is not repeated here.

The package connection pad 162 is formed on a portion of the upper surface of the first semiconductor chip 112. The package connection pad 162 may be formed in contact with the package connection member 200A-3 and electrically and/or physically connected to the second semiconductor package 200 through the package connection member 200A-3. In addition, the package connection pad 162 may be formed on the first semiconductor chip 112 and connected to the substrate 20 through the upper pad 132 and the bonding wire 152 to thereby function to electrically connect the second semiconductor package 200 to the substrate 20.

A molding member 176 is formed to cover the upper surface and the side surfaces of the first semiconductor chip 112 and to cover the upper pad 132 and the bonding wire 152. Unlike the molding members 170 and 172 illustrated in FIGS. 1 and 2, the molding member 176 may be formed to have the upper pad 132 and the bonding wire 152 therein. In exemplary embodiments in accordance with principles of inventive concepts a material and a forming method of the molding member 176 are the same as those of the molding member 170 described with reference to FIG. 1, and thus, a detailed description thereof is not repeated here.

An opening part 176T of the molding member 176 may be formed on a portion of the upper surface of the first semiconductor chip 112. The package connection member 200A-3 and the underfill member 200U-3 may be formed in the opening part 176T. An upper surface region of the upper surface of the first semiconductor package 102, in which the package connection member 200A-3 for connecting the upper pad 162 and the second semiconductor package 200 is formed, may be formed in a surface-exposed form without being covered and sealed by the molding member 176.

The underfill member 200U-3 may be interposed between the region of the upper surface of the first semiconductor package 102 without covered by the molding member 176 and the lower surface of the second semiconductor chip package 200-1 located at the lowest part of the second semiconductor package 200. In exemplary embodiments in accordance with principles of inventive concepts a material and a forming method of the underfill member 200U-3 are the same as those of the underfill member 200U described with reference to FIG. 1, and thus, a detailed description thereof is not repeated here.

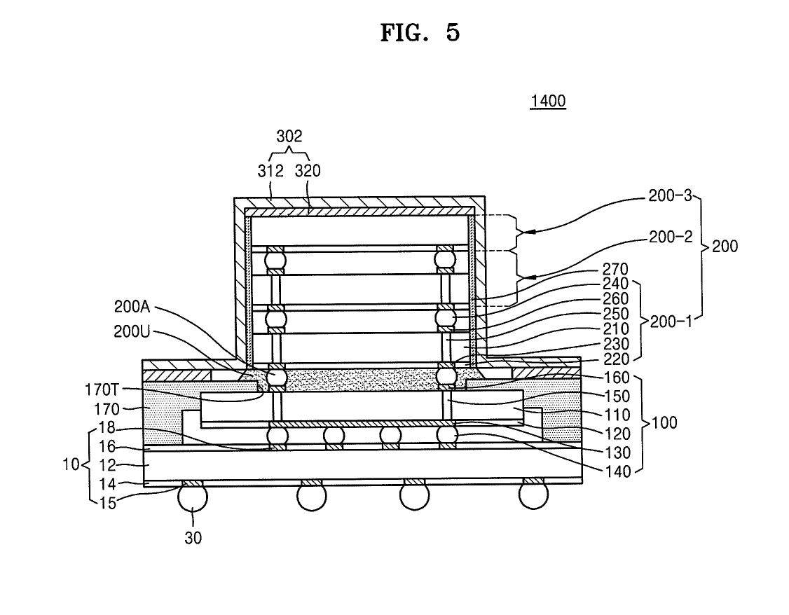

FIG. 5 is a cross-sectional view of a semiconductor package 1400 according to another exemplary embodiment in accordance with principles of inventive concepts. Semiconductor package 1400 may include the substrate 10, the first semiconductor package 100, the second semiconductor package 200, the package connection member 200A, the underfill member 200U, and a heat-dissipation member 302. The semiconductor package 1400 illustrated in FIG. 5 differs from the semiconductor package 1000 illustrated in FIG. 1 only in a shape and an arrangement relationship of the heat-dissipation member 302, having the same components, and thus, like reference numerals in FIG. 1 denotes like elements. A detailed description of components described with reference to FIG. 1 is not repeated here.

The heat-dissipation member 302 may include a heat-dissipation plate 312 and the adhesive member 320. The heat-dissipation plate 310 may be a thermal via or a heat slug, for example. The heat-dissipation plate 312 may be formed to cover a portion of the upper surface of the molding member 170 of the first semiconductor package 100 and the uppermost surface and the side surfaces of the second semiconductor package 200. In exemplary embodiments in accordance with principles of inventive concepts heat-dissipation plate 312 may be formed with a constant thickness. Compared with the heat-dissipation plate 310 illustrated in FIG. 1, the heat-dissipation plate 312 differs in that the heat-dissipation plate 312 is formed in contact with the side surfaces of the second semiconductor package 200. As described above, the heat-dissipation plate 312 is formed in contact with the side surfaces of the second semiconductor package 200, and is thereby capable of further reducing a form factor of the upper package and allowing the whole semiconductor package 1400 to be implemented with relatively small scaling and high integration. In addition, because there is no separate space between the side surfaces of the second semiconductor package 200 and the heat-dissipation plate 312, heat generated by the first semiconductor package 100 or heat generated by the second semiconductor package 200 may be directly dissipated through the heat-dissipation plate 312, thereby resulting in high heat-dissipation efficiency.

In exemplary embodiments in accordance with principles of inventive concepts materials and forming methods of the heat-dissipation plate 312 and the adhesive member 320 are the same as those of the heat-dissipation plate 310 and the adhesive member 320 illustrated in FIG. 1, and thus, a detailed description thereof is not repeated her.

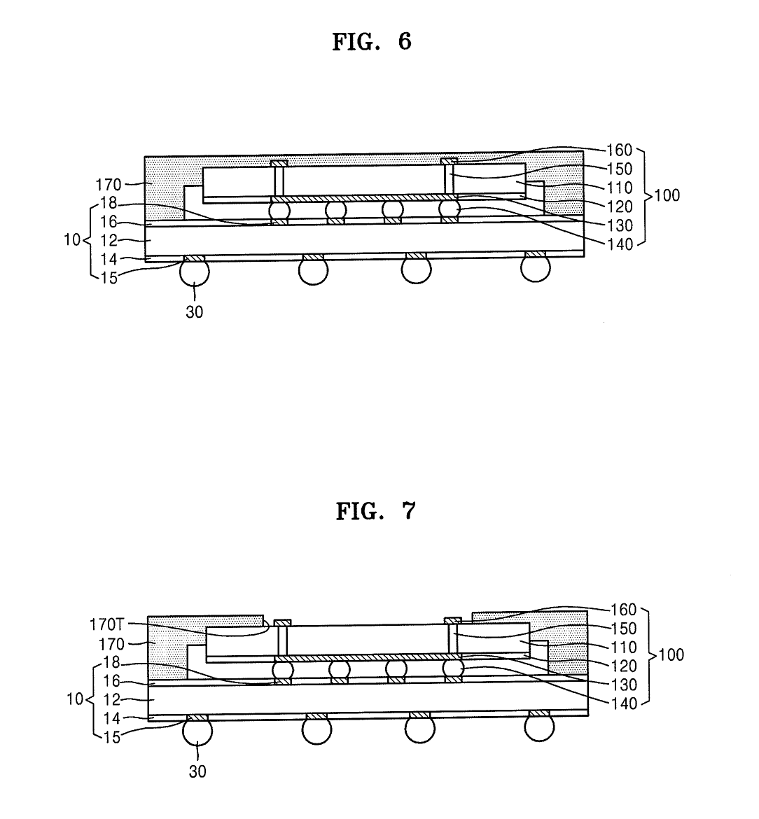

FIGS. 6 to 9 are cross-sectional views sequentially showing a portion of a method of manufacturing the semiconductor package 1000 of a POP structure, in accordance with principles of inventive concepts. First semiconductor chip 110 and first package connection members are bonded onto the substrate 10, and the molding member 170 that covers the first semiconductor chip 110 is formed.

More particularly, the first semiconductor chip 110 is bonded onto the substrate 10. The first semiconductor chip 110 may be bonded to a center part where the connection member 140 included in the substrate 10 is formed. The lower wiring pattern 130 formed on the lower surface of the first semiconductor chip 110 may be electrically connected to the substrate 10 through the connection member 140. In addition, the first semiconductor chip 110 may be electrically connected to the first through-electrode 150 through the connection member 140. The connection member 140 may be a solder ball and may be bonded to the upper pad 18 of the substrate 10 by using a thermocompression process and/or a reflow process, for example. In exemplary embodiments in accordance with principles of inventive concepts, the first semiconductor chip 110 may be plural in number.

Thereafter, the molding member 170 for sealing the first semiconductor chip 110 is formed. In exemplary embodiments in accordance with principles of inventive concepts molding member 170 is formed to cover the whole upper surface and a portion of the side surfaces of the first semiconductor chip 110 and a portion of the upper surface of the substrate 10. That is, the molding member 170 may completely seal the upper surface of the first semiconductor chip 110. Although FIG. 6 shows that a space between the lower surface of the first semiconductor chip 110 and the upper surface of the substrate 10 is vacant, inventive concepts are not limited thereto, and in other exemplary embodiments the space may be fully sealed by the molding member 170.

Referring to FIG. 7, in exemplary embodiments in accordance with principles of inventive concepts the molding member 170 located on the first semiconductor chip 110 is removed. More particularly, the molding member 170 formed in a region of a center part of the upper surface of the first semiconductor chip 110, in which the upper pad 160 is formed, is removed. By removing a portion of the molding member 170, the opening part 170T through which the upper pad 160 of the first semiconductor package 100 is exposed is formed. The opening part, also referred to herein simply, as “opening,” 170T may be formed by using a lithography etching process or a laser drill process (LDP) using a laser, for example. The opening part 170T may extend in a lower direction with a constant width or a gradually narrowed width. In addition, in the removing operation described above, the first semiconductor chip 110 may be thinned by removing an upper part of the first semiconductor chip 110, thereby reducing the thickness of the first semiconductor chip 110 to a predetermined thickness.

Through the removing operation described above, the uppermost surface of the molding member 170 which was formed in the center part of the first semiconductor chip 110 may be recessed, and accordingly, the center part of the upper surface of the first semiconductor chip 110 and the upper pad 160 may be exposed. The level of the uppermost surface of the molding member 170 formed on an edge of the first semiconductor chip 110 may be higher than the level of the uppermost surface of the first semiconductor chip 110. The portion of the molding member 170 which is formed to cover the edge of the first semiconductor chip 110 may function as a buffer for heat or stress concentrated due to an operation of the first semiconductor chip 110 or an external influence.

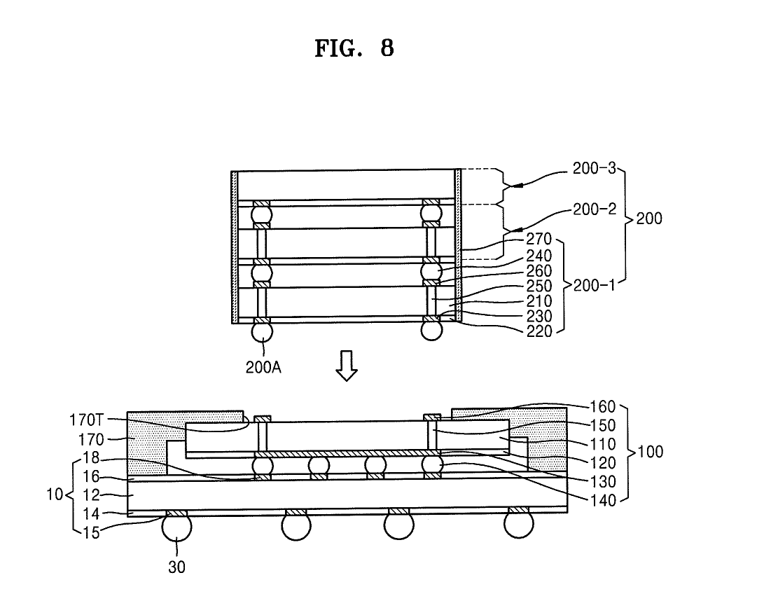

Referring to FIG. 8, the second semiconductor package 200 is bonded to the upper surface of the first semiconductor chip 110 and the upper surface of the molding member 170. In exemplary embodiments in accordance with principles of inventive concepts the bonding operation may include the operations to be described below. The second semiconductor package 200 including the lower pad 230 of the second semiconductor chip package 200-1, which is located in correspondence with the upper pad 160 formed on the first semiconductor chip 110, is provided. That is, the second semiconductor package 200 is located on the first semiconductor package 100 so that the lower pad 230 of the second semiconductor chip package 200-1 formed on the lowest part of the second semiconductor package 200 is connected to and matches the upper pad 160 of the first semiconductor chip 110. Thereafter, the package connection member 200A is inserted into the opening part 170T so that the upper pad 160 is electrically and/or physically connected to the lower pad 230. The package connection member 200A may connect the first semiconductor package 100 to the second semiconductor package 200 through a thermo-compression process and/or a reflow process, for example.

The package connection member 200A may include, for example, a Cu pillar, solder, and an anisotropic conductive film (ACF), and when the package connection member 200A is formed as a single layer, the package connection member 200A may be formed of Sn—Ag solder or Cu, for example. ACF has a structure in which conductive particles are spread in an insulating adhesive film, allowing a current to flow only in an electrode direction, for example, a vertical direction, in connection, and has an anisotropic electrical characteristic of being insulated in an inter-electrode direction, for example, a horizontal direction. In exemplary embodiments in accordance with principles of inventive concepts, with the ACF, when an adhesive is melted by applying heat and a pressure, conductive particles are aligned between electrodes facing each other to thereby generate conductivity between the facing electrodes, whereas the adhesive is filled between adjacent electrodes to thereby insulate the adjacent electrodes from each other.

In exemplary embodiments in accordance with principles of inventive concepts, the package connection member 200A is not limited to the materials described above and may be formed of various other adhesive materials capable of rigidly bonding chips and sealing connection members and pads at connection parts.

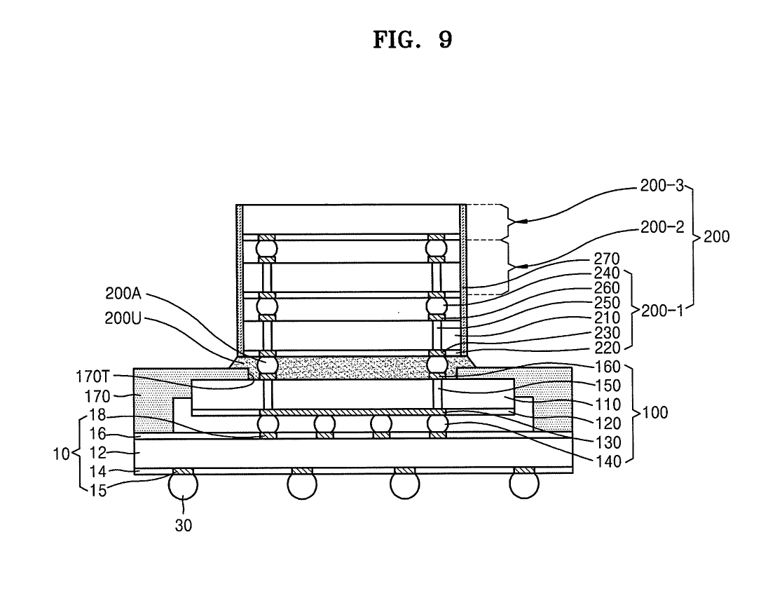

Referring to FIG. 9, the underfill member 200U is formed to cover a portion of the upper surface of the first semiconductor chip 110 and a portion of the upper surface of the molding member 170 and to be in contact with both side surfaces of the upper pad 160 formed on the first semiconductor chip 110. In exemplary embodiments in accordance with principles of inventive concepts, underfill member 200U may fill between the upper surface of the first semiconductor package 100 and the lower surface of the second semiconductor package 200 and seal between a portion of the upper surfaces of the molding member 170 and the first semiconductor package 100. The underfill member 200U may be formed of an underfill resin, such as an epoxy resin, and may include a silica filler or flux, for example.

In exemplary embodiments in accordance with principles of inventive concepts, an adhesive member may be used instead of the underfill member 200U. The adhesive member may include, for example, a non-conductive adhesive film (NCF), an ACF, a UV film, an instantaneous adhesive, a thermosetting adhesive, a laser-curable adhesive, an ultrasound-curable adhesive, a non-conductive paste (NCP), for example.

Thereafter, the heat-dissipation member 300 may be formed on the upper surface of the second semiconductor chip package 200-3 and the upper surface of the molding member 170, thereby manufacturing the semiconductor package 1000 of a POP structure in accordance with principles of inventive concepts. A material and a forming method of the heat-dissipation member 300 have been described with reference to FIG. 1, and thus a detailed description thereof is not repeated here.

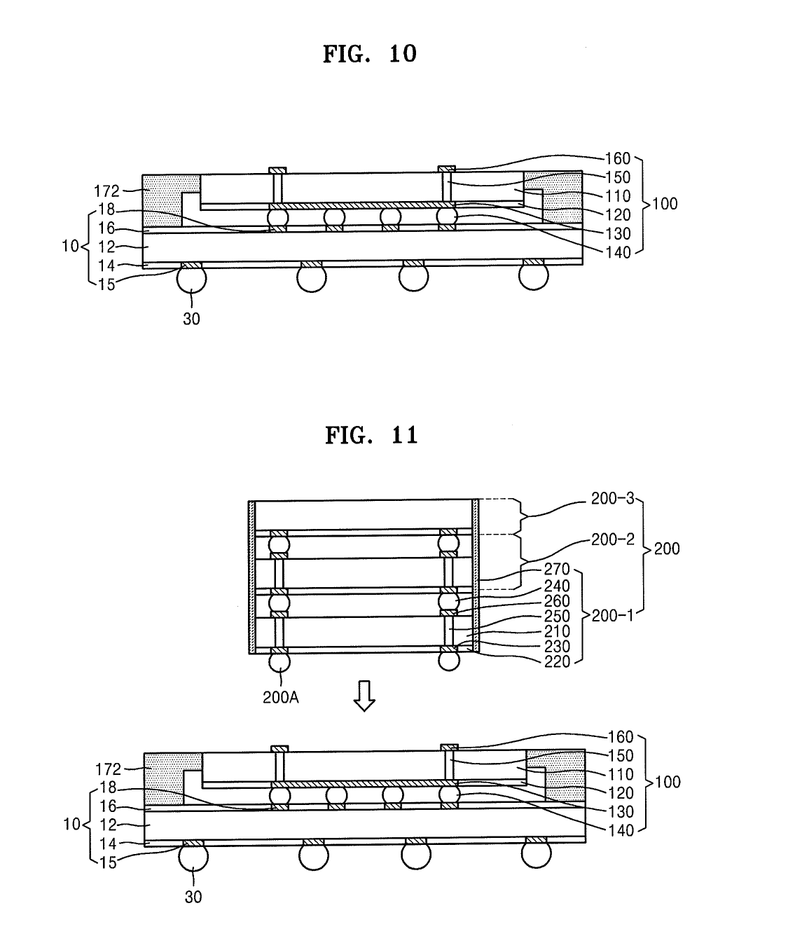

FIGS. 10 to 12 are cross-sectional views sequentially showing a portion of a method of manufacturing the semiconductor package 1100 of a POP structure, according to another exemplary embodiment in accordance with principles of inventive concepts.

Referring to FIG. 10, the first semiconductor chip 110 and the first package connection members are bonded onto the substrate 10, and the molding member 172 that covers the first semiconductor chip 110 is formed. In exemplary embodiments in accordance with principles of inventive concepts, a manufacturing process illustrated in FIG. 10 is the same as the manufacturing process illustrated in FIG. 6 except for a method of forming the molding member 172, and thus, a detailed description thereof is not repeated here.

The molding member 172 that seals the first semiconductor chip 110 is formed to cover a portion of the side surfaces of the first semiconductor chip 110 and a portion of the upper surface of the substrate 10. That is, unlike the molding member 170 illustrated in FIG. 6, the molding member 172 is formed to contact the portion of the side surfaces of the first semiconductor chip 110 without fully sealing the first semiconductor chip 110. The molding member 172 may be formed of an epoxy-group material, a thermosetting material, a thermoplastic material, a UV treated material, for example, wherein a level of the upper surface of the molding member 172 may be the same as that of the first semiconductor chip 110 by adding the epoxy-group material or the like by a predetermined amount and performing an MUF process through time and temperature control.

If the MUF process is performed as illustrated in FIG. 10, the upper pad 160 of the first semiconductor chip 110 may be exposed even without a separate recess process, thereby laminating the second semiconductor package 200 (see FIG. 11) thereon and electrically connecting the second semiconductor package 200 thereto.

Referring to FIG. 11, the second semiconductor package 200 is bonded onto the first semiconductor chip 110. The exposed upper pad 160 is located to match the lower pad 230 of the second semiconductor chip package 200-1 formed at the lowest part of the second semiconductor package 200, and the package connection member 200A is formed between the upper pad 160 and the lower pad 230. In exemplary embodiments in accordance with principles of inventive concepts, an electrical connection relationship between the first semiconductor package 100 and the second semiconductor package 200 is the same as described with reference to FIG. 2, and thus, a detailed description thereof is not repeated here.

The package connection member 200A may connect the first semiconductor package 100 to the second semiconductor package 200 through a thermo-compression process and/or a reflow process, for example. In exemplary embodiments in accordance with principles of inventive concepts, a material and a forming method of the package connection member 200A are the same as described with reference to FIG. 8, and thus, a detailed description thereof is not repeated here.

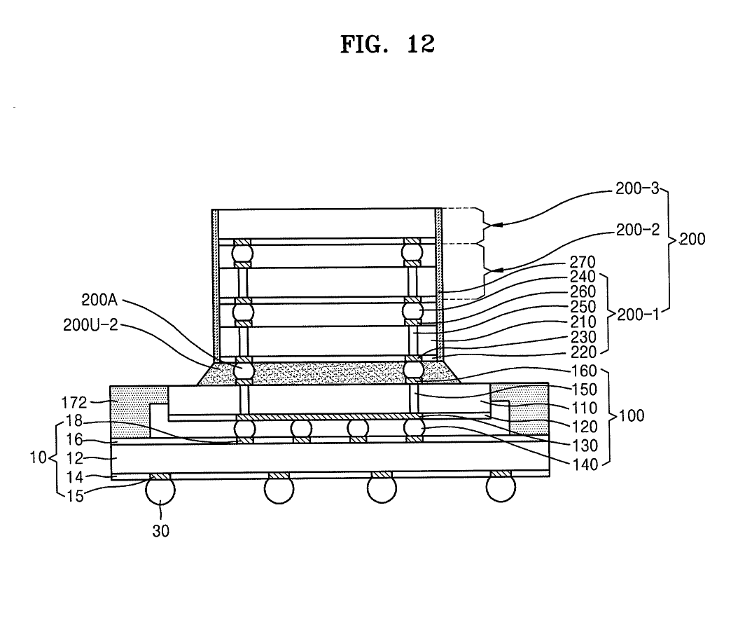

Referring to FIG. 12, the underfill member 200U-2 is formed between the upper surface of the first semiconductor chip 110 and the lower surface of the second semiconductor chip package 200-1 formed at the lowest part of the second semiconductor package 200. Unlike the underfill member 200U described with reference to FIG. 9, the underfill member 200U-2 is formed to cover the whole upper surface of the first semiconductor chip 110 and to not contact the molding member 172 because the molding member 172 has been formed so as to not cover the upper surface of the first semiconductor chip 110 in FIG. 10. In exemplary embodiments in accordance with principles of inventive concepts, a material and a forming method of the underfill member 200U-2 are the same as described with reference to FIG. 9, and thus a detailed description thereof is not repeated here.

Thereafter, the heat-dissipation member 300 may be formed on the upper surface of the second semiconductor chip package 200-3 and a portion of the upper surface of the molding member 172, thereby manufacturing the semiconductor package 1100 of a POP structure in accordance with principles of inventive concepts. In exemplary embodiments in accordance with principles of inventive concepts, a material and a forming method of the heat-dissipation member 300 have been described with reference to FIG. 1, and thus a detailed description thereof is not repeated here.

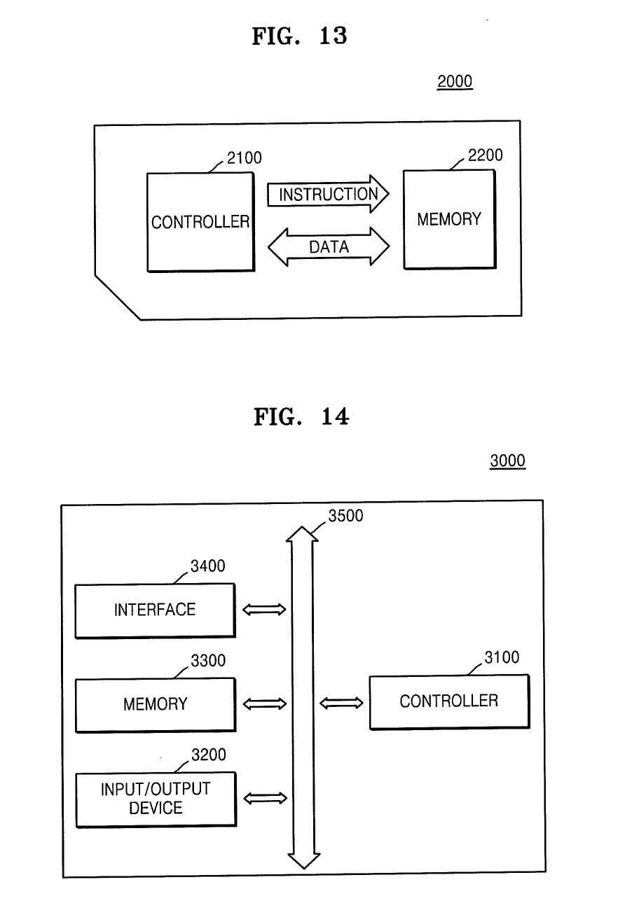

FIG. 13 is a block diagram of a memory card 2000 including a semiconductor package in accordance with principles of inventive concepts. In the memory card 2000, a controller 2100 and a memory 2200 may be arranged to exchange electrical signals. For example, when the controller 2100 sends an instruction, the memory 2200 may send data. The controller 2100 and/or the memory 2200 may include a semiconductor package in accordance with principles of inventive concepts. In particular, the controller 2100 may include the first semiconductor package(s) 100, 100-1 and 100-2, or 102 in the semiconductor package 1000, 1100, 1200, 1300, or 1400 in accordance with principles of inventive concepts, and the memory 2200 may include the second semiconductor package 200 in the semiconductor package 1000, 1100, 1200, 1300, or 1400 in accordance with principles of inventive concepts, for example.

The memory card 2000 may be used for memory apparatuses such as various types of cards, for example, a memory stick card, a smart media (SM) card, a secure digital (SD) card, a mini SD card, or a multi-media card (MMC).

FIG. 14 is a block diagram of an electronic system 3000 including a semiconductor package in accordance with principles of inventive concepts. Electronic system 3000 may include a controller 3100, an input/output device 3200, a memory 3300, and an interface 3400. The electronic system 3000 may be a mobile system or a system for transmitting or receiving information. The mobile system may be a personal digital assistant (PDA), a portable computer, a web tablet, a wireless phone, a mobile phone, a digital music player, or a memory card, for example.

The controller 3100 may function to execute a program and to control the electronic system 3000. The controller 3100 may be, for example, a microprocessor, a digital signal processor, a microcontroller, or a similar device. The input/output device 3200 may be used to input or output data into or from the electronic system 3000.

The electronic system 3000 may exchange data with an external device, for example, a personal computer (PC) or a network, by connecting to the external device using the input/output device 3200. The input/output device 3200 may be, for example, a keypad, a keyboard, or a display. The memory 3300 may store codes and/or data for an operation of the controller 3100 and/or store data processed by the controller 3100. The controller 3100 and the memory 3300 may include the semiconductor package 1000, 1100, 1200, 1300, or 1400 in accordance with principles of inventive concepts. In particular, the controller 3100 may include the first semiconductor package(s) 100, 100-1 and 100-2, or 102 in the semiconductor package 1000, 1100, 1200, 1300, or 1400 in accordance with principles of inventive concepts, and the memory 3300 may include the second semiconductor package 200 in the semiconductor package 1000, 1100, 1200, 1300, or 1400 in accordance with principles of inventive concepts, for example. The interface 3400 may be a data transmission path between the electronic system 3000 and an external device. The controller 3100, the input/output device 3200, the memory 3300, and the interface 3400 may communicate with each other via a bus 3500.

For example, the electronic system 3000 may be used for mobile phones, MP3 players, navigation machines, portable multimedia players (PMPs), solid state disks (SSDs), and household appliances.

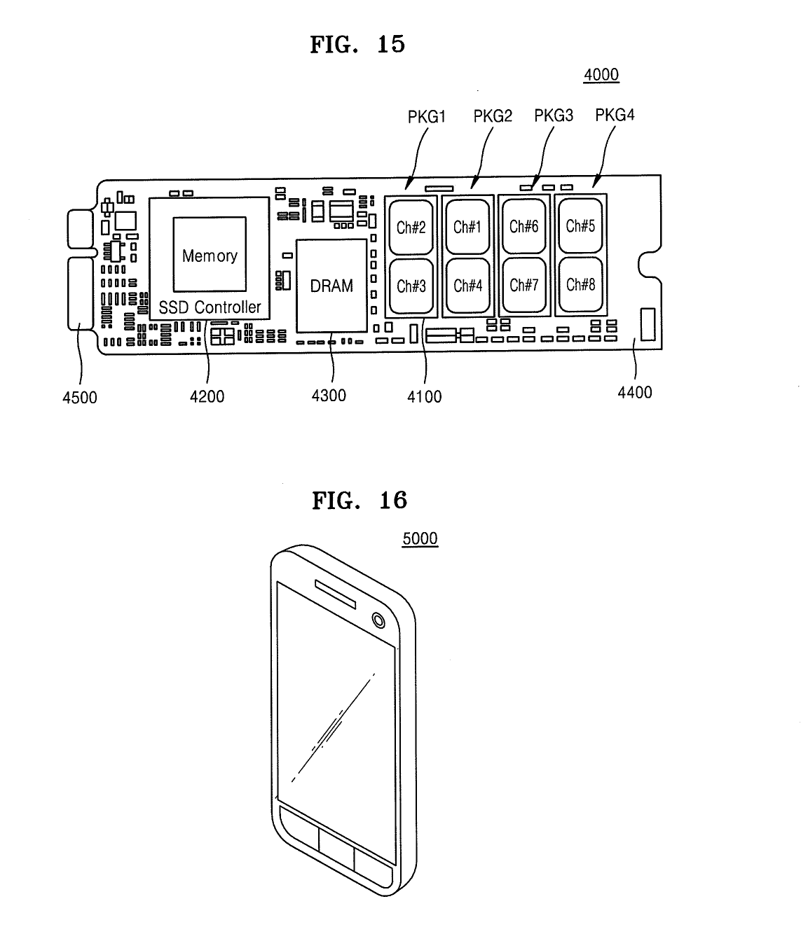

FIG. 15 is a top view of a solid state drive (SSD) device 4000 to which a semiconductor package in accordance with principles of inventive concepts is applied, wherein the electronic system 3000 of FIG. 14 is applied to the SSD device 4000. The SSD device 4000 in accordance with principles of inventive concepts may include a memory package 4100, an SSD controller package 4200, a DRAM 4300, and a main board 4400.

The memory package 4100, the SSD controller package 4200, the DRAM 4300 may include the semiconductor package 1000, 1100, 1200, 1300, or 1400 in accordance with principles of inventive concepts. The memory package 4100 may be mounted on the main board 4400 through an external connection member (refer to 240 of FIG. 1), and as shown in FIG. 15, the memory package 4100 may include four memory packages PKG1, PKG2, PKG3, and PKG4. However, inventive concepts are not limited thereto, and the memory package 4100 may include a greater number of memory packages according to a channel support state of the SSD controller package 4200, for example. When the memory package 4100 is configured with multiple channels, the memory package 4100 may include three or less memory packages, for example.

The memory package 4100 may be mounted on the main board 4400 in a ball grid array (BGA) method through an external connection member, such as a solder ball). However, inventive concepts are not limited thereto, and memory package 4100 may be mounted on the main board 4400 in another method. For example, the memory package 4100 may be mounted on the main board 4400 in a pin grid array (PGA) method, an MPGA method, a tape carrier package (TCP) method, a chip-on-board (COB) method, a quad flat non-leaded (QFN) method, a quad flat package (QFP) method, for example.

The memory package 4100 may include at least one of the semiconductor packages 1000, 1100, 1200, 1300, and 1400 in accordance with principles of inventive concepts.

The SSD controller package 4200 may include eight channels, and the eight channels may be one-to-one connected to corresponding channels of the four memory packages PKG1, PKG2, PKG3, and PKG4 to thereby control semiconductor chips in the memory package 4100.

The SSD controller package 4200 may include a program capable of transmitting and receiving signals to and from an external device in a method based on a serial advanced technology attachment (SATA) standard, a parallel advanced technology attachment (PATA) standard, or a small computer system interface (SCSI) standard, for example. The SATA standard may include all SATA-group standards, such as SATA-1, SATA-2, SATA-3, external SATA (e-SATA), for example. The PATA standard may include all integrated drive electronics (IDE)-group standards, such as IDE, enhanced IDE (E-IDE), for example.

The SSD controller package 4200 may control EEC or FTL processing. The SSD controller package 4200 may also be mounted on the main board 4400 in a package form. Like the memory package 4100, the SSD controller package 4200 may be mounted on the main board 4400 in a BGA method, a PGA method, an MPGA method, a TCP method, a COB method, a QFN method, or a QFP method, for example.

The SSD controller package 4200 may include at least one of the semiconductor packages 1000, 1100, 1200, 1300, and 1400 in accordance with principles of inventive concepts.

The DRAM 4300 is an auxiliary memory device and may function as a buffer in a data exchange between the SSD controller package 4200 and the memory package 4100. The DRAM 4300 may also be mounted on the main board 4400 in various methods, such as a BGA method, a PGA method, an MPGA method, a TCP method, a COB method, a QFN method, a QFP method, for example.

The main board 4400 may be a PCB, a flexible PCB, an organic substrate, a ceramic substrate, a tape substrate, for example. The main board 4400 may include, for example, a core board having an upper surface and a lower surface and resin layers respectively formed on the upper surface and the lower surface. The resin layers may be formed in a multi-layer structure, and a signal layer, a ground layer, and/or a power layer forming a wiring pattern may be interposed in the multi-layer structure. A separate wiring pattern may be formed on the resin layers. In FIG. 15, minute patterns on the main board 4400 may indicate wiring patterns or a plurality of passive elements. An interface 4500 for communicating with an external device may be formed on one side, for example, the left side, of the main board 4400.

FIG. 16 is a perspective view of an electronic device to which a semiconductor package in accordance with principles of inventive concepts is applied.

FIG. 16 is an example in which the electronic system 3000 of FIG. 14 is applied to a mobile phone 5000. In exemplary embodiments in accordance with principles of inventive concepts, electronic system 3000 may be applied to portable laptop computers, MP3 players, navigation machines, SSDs, vehicles, and household appliances, for example.

While inventive concepts have been particularly shown and described with reference to exemplary embodiments thereof, it will be understood that various changes in form and details may be made therein without departing from the spirit and scope of inventive concepts.

What is claimed is:

1. A semiconductor package of a package on package (POP) structure, comprising:
a substrate having a connection terminal on the upper surface thereof;
a first semiconductor package including a first semiconductor chip mounted on the substrate and connected to the connection terminal, the first semiconductor package also including a molding member covering only a portion of the upper surface of the first semiconductor chip and the side surfaces thereof;
a second semiconductor package including a plurality of second semiconductor chips which are stacked in a multi-layer structure, the second semiconductor chips having a second semiconductor chip through-electrode by which the second semiconductor chips are connected to each other; and
a connection member disposed on a portion of the upper surface of the first semiconductor package left exposed by the molding member,
wherein the second semiconductor package is mounted on the first semiconductor package and electrically connected to the first semiconductor package through the connection member.

2. The semiconductor package of claim 1, wherein the first semiconductor package includes a plurality of first semiconductor chips respectively having a plurality of first semiconductor chip through-electrodes, the first semiconductor chips electrically connected to each other through the plurality of first semiconductor chip through-electrodes.

3. The semiconductor package of claim 1, wherein the first semiconductor package comprises a plurality of connection pads on the upper surface thereof and a wire to electrically connect the plurality of connection pads and the substrate.

4. The semiconductor package of claim 1, wherein the first semiconductor chip is a different type of chip from the second semiconductor chips.

5. The semiconductor package of claim 1, wherein the first semiconductor chip comprises a logic semiconductor chip, and the plurality of second semiconductor chips comprise a memory semiconductor chip.

6. The semiconductor package of claim 1, wherein the plurality of second semiconductor chips are connected to each other via a micro pillar grid array (MPGA).

7. The semiconductor package of claim 1, wherein a planar area of the first semiconductor package is greater than that of the second semiconductor package.

8. The semiconductor package of claim 1, wherein the uppermost surface of the molding member is formed at substantially the same level as the uppermost surface of the first semiconductor chip.

9. The semiconductor package of claim 1, further comprising a heat-dissipation member which covers the upper surface of the molding member and the upper surface of the second semiconductor package.

10. The semiconductor package of claim 9, wherein the heat-dissipation member is of a constant thickness on the upper surface of the second semiconductor package and the upper surface of the first semiconductor package and further comprises a bonding member interposed between the heat-dissipation member and the upper surface of the second semiconductor package and between the heat-dissipation member and a portion of the upper surface of the first semiconductor package

11. A semiconductor package of a package on package (POP) structure, comprising:
a substrate having a connection terminal formed on the upper surface thereof;
a first semiconductor package including a first semiconductor chip mounted on the substrate and connected to the connection terminal;
a second semiconductor package including a plurality of second semiconductor chips; and
a connection member interposed between the first semiconductor chip and the plurality of second semiconductor chips,
wherein the second semiconductor package is mounted on the upper surface of the first semiconductor package, the first semiconductor chip is directly connected to the plurality of second semiconductor chips through the connection member, and an underfill member which partially covers the connection member is disposed between the upper surface of the first semiconductor package and the lower surface of the second semiconductor package.

12. The semiconductor package of claim 11, wherein the plurality of second semiconductor chips are stacked in a multi-layer structure and are connected to each other via a micro pillar grid array (MPGA).

13. The semiconductor package of claim 11, further comprising a molding member which covers a portion of the upper surface of the first semiconductor package and the side surfaces thereof,
wherein the molding member is disposed so that at least a portion of the upper surface thereof contacts the underfill member.

14. The semiconductor package of claim 11, further comprising a molding member which covers the side surfaces of the first semiconductor package,
wherein the uppermost surface of the molding member is formed at the same level as the uppermost surface of the first semiconductor package.

15. The semiconductor package of claim 14, wherein the molding member is spaced by a predetermined distance from the underfill member.

16. A semiconductor package, comprising:
a substrate having a connection terminal on the upper surface thereof;
a first semiconductor package including a first semiconductor chip mounted on the substrate and connected to the connection terminal, the first semiconductor package also including a molding member covering only a portion of the upper surface of the first semiconductor chip and the side surfaces thereof;
a second semiconductor package including a plurality of second semiconductor chips which are stacked in a multi-layer structure, the second semiconductor chips having a second semiconductor chip through-electrode by which the second semiconductor chips are connected to each other;
a connection member disposed on a portion of the upper surface of the first semiconductor package left exposed by the molding member, wherein the second semiconductor package is mounted on the first semiconductor package and electrically connected to the first semiconductor package through the connection member which extends through an underfill member in contact with the upper surface of a semiconductor chip in the first semiconductor package and with the lower surface of a lower-most semiconductor chip of the second semiconductor package; and
a heat-dissipation member which covers the upper surface of the molding member and the upper surface of the second semiconductor package.

17. The semiconductor package of claim 16, wherein the second semiconductor chips are all the same type of chip.

18. An electronic system including the semiconductor package of claim 17, wherein the second semiconductor chips are memory chips.

19. A solid state drive (SSD) including the electronic system of claim 18, wherein the first semiconductor chip is a memory controller.

20. A mobile telephone including the semiconductor package of claim 16.
